(19) United States
(12) Patent Application Publication
(10) Pub. No.: US 2023/0352384 A1
(43) Pub. Date: Nov. 2, 2023

(54) THIN DIELECTRIC SUBSTRATE FOR LOW THERMAL RESISTANCE AND LOW PARASITIC INDUCTANCE

(71) Applicant: Lumentum Operations LLC, San Jose, CA (US)

(72) Inventors: Wei SHI, San Jose, CA (US); Mikhail DOLGANOV, San Jose, CA (US); Steve CHEUNG, San Jose, CA (US); Lijun ZHU, Dublin, CA (US)

(21) Appl. No.: 18/188,622

(22) Filed: Mar. 23, 2023

Related U.S. Application Data
(60) Provisional application No. 63/362,311, filed on Mar. 31, 2022.

(51) Int. Cl. H01L 23/498; H05K 3/46; H05K 1/11; H05K 1/03; H05K 1/16

(52) U.S. Cl. CPC H01L 23/49822; H05K 1/0306; H05K 1/115; H05K 1/162; H05K 3/4688; H05K 2201/0187; H05K 2201/09563

(57) ABSTRACT

In some implementations, a substrate comprises a ceramic core, multiple metal-filled vias through the ceramic core, and a first metal layer, on a top side of the ceramic core, including metal traces, over respective metal-filled vias. The substrate comprises a second metal layer, including a first electrical contact over a first metal trace, a second electrical contact over a second metal trace, and a third electrical contact over a third metal trace, where the second metal trace is electrically isolated from the first and third metal traces. The substrate comprises a thin dielectric layer separating the first metal layer and the second metal layer. The dielectric layer between the first metal layer and the second layer provides the substrate with a low parasitic inductance and a low thermal resistance based on a thickness of the dielectric layer and/or a material used for the dielectric layer.

### CROSS-REFERENCE TO RELATED APPLICATION

This Pat. Application claims priority to U.S. Provisional Pat. Application No. 63/362,311, filed on Mar. 31, 2022, and entitled “TIME-OF-FLIGHT CAMERA PROJECTOR WITH ULTRA-THIN DIELECTRIC SUBSTRATE FOR LOW THERMAL RESISTANCE AND LOW PARASITIC INDUCTANCE.” The disclosure of the prior Application is considered part of and is incorporated by reference into this Patent Application.

### TECHNICAL FIELD

The present disclosure relates generally to substrate designs for forming a current loop across two metal layers that are separated by a thin dielectric coating or a thin dielectric layer that provides a low thermal resistance and a low parasitic inductance.

### BACKGROUND

Chip submounts are components that are used in the electronics industry to provide a platform for mounting microelectronic devices, such as chips and die, onto a printed circuit board (PCB) or other substrate. The chip submounts typically serve as an intermediate stage in the assembly of microelectronic devices, allowing for easy handling, testing, and protection of the sensitive devices before final assembly. Chip submounts typically include a base material, such as ceramic or metal, and a bonding surface that allows the microelectronic device to be attached. Chip submounts play an important role in the performance and reliability of microelectronic devices by providing electrical and thermal connections between the microelectronic device and the substrate. For example, the electronical contacts of a chip submount provide the necessary pathways for the microelectronic device to communicate with other components on the substrate, while thermal interface materials help to dissipate heat that the microelectronic device generates during operation. In addition, chip submounts can provide mechanical support to the microelectronic device, which reduces the risk of physical damage during handling and assembly. With advancements in microelectronics and increasing demand for higher performance devices, the use of chip submounts continues to grow and evolve.

### SUMMARY

In some implementations, a substrate includes a ceramic core; a plurality of metal-filled vias through the ceramic core; a first metal layer, on a top side of the ceramic core, including: a first metal trace, over and connected to a first metal-filled via of the plurality of metal-filled vias, a second metal trace, over and connected to a second metal-filled via of the plurality of metal-filled vias, and a third metal trace, over and connected to a third metal-filled via of the plurality of metal-filled vias, wherein the second metal trace is electrically isolated from the first metal trace and the third metal trace; a thin dielectric layer on the first metal layer, wherein the thin dielectric layer has a low thermal resistance based on one or more of the thickness of the thin dielectric layer or a material used for the thin dielectric layer; and a second metal layer, on the thin dielectric layer, including: a first electrical contact over the first metal trace and electrically isolated from the first metal trace, a second electrical contact over the second metal trace and electrically connected to the second metal trace, and a third electrical contact over the third metal trace and electrically connected to the third metal trace, wherein the second electrical contact is electrically isolated from the first electrical contact and the third electrical contact.

In some implementations, a circuit includes a ceramic core comprising a plurality of metal-filled vias through the ceramic core; a first metal layer, on a top side of the ceramic core, including a plurality of metal traces over and connected to the plurality of metal-filled vias, wherein the plurality of metal traces include one or more first metal traces and one or more second metal traces, wherein the one or more second metal traces are each electrically isolated from the rest of the plurality of metal traces; a thin dielectric on the first metal layer, wherein the thin dielectric has a low thermal resistance based on one or more of a thickness of the thin dielectric or a material used to form the thin dielectric; a second metal layer, on the thin dielectric, including: an anode over and electrically isolated from the plurality of metal traces by the thin dielectric; a cathode pad over and electrically connected to at least one of the one or more second metal traces by a first via through the thin dielectric; and a ground over and electrically connected to the one or more first metal traces by a second via through the thin dielectric; and a capacitor connected to the ground, wherein the thin dielectric between the first metal layer and the second metal layer provides the circuit with a low parasitic inductance and a low thermal resistance during operation.

In some implementations, a method includes receiving a substrate that includes a ceramic core, a plurality of metal-filled vias through the ceramic core, and a first metal layer, on a top side of the ceramic core, including one or more metal traces; depositing, on top of the ceramic core and the first metal layer, a dielectric layer that comprises: an aluminum oxynitride (AlON) layer with a thickness in a range from one micrometer (µm) to sixty µm, an aluminum phosphate (AlPO₄) layer with a thickness in a range from 0.01 µm to sixty µm, an aluminum oxide (Al₂O₃) layer with a thickness in a range from 0.3 µm to one µm, or a silicon dioxide (SiO₂) layer with a thickness in a range from 0.3 µm to one µm; and forming, on the dielectric layer, a second metal layer including a floating contact over a first metal trace, a signal contact over a second metal trace, and a ground contact over a third metal trace.

### BRIEF DESCRIPTION OF THE DRAWINGS

FIG. 1 is a diagram illustrating an example of a complementary metal-oxide-semiconductor (CMOS) chip.

FIG. 2 is a diagram illustrating examples of vertical-cavity surface-emitting laser (VCSEL) chips connected to a substrate.

FIG. 3A is a diagram illustrating an example of a time-of-flight (ToF) projector module.

FIG. 3B is a diagram illustrating an example of a current loop that may be formed horizontally in one metal layer to drive an optical load in a ToF projector module.

FIGS. 3C-3D are diagrams illustrating examples of current loops that may be formed vertically in two metal layers to drive an optical load in a ToF projector module.

FIG. 4 is a diagram illustrating example substrates with a high thermal resistance and/or a high parasitic inductance.

FIGS. 5A-5B are diagrams illustrating example implementations of a substrate that comprises a ceramic core with two metal layers that are separated by a thin dielectric layer to enable a low thermal resistance and a low parasitic inductance.

FIG. 6 is a diagram illustrating an example circuit in which the substrate shown in FIG. 5A is mounted to a printed circuit board and an integrated capacitor is formed on a top metal layer of the substrate.

### DETAILED DESCRIPTION

The following detailed description of example implementations refers to the accompanying drawings. The same reference numbers in different drawings may identify the same or similar elements.

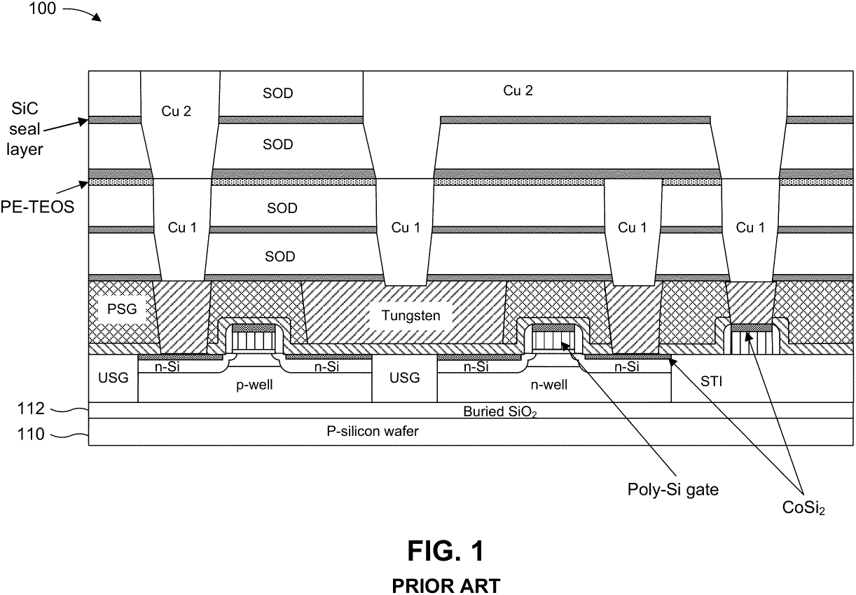

FIG. 1 is a diagram illustrating an example 100 of a complementary metal-oxide-semiconductor (CMOS) chip. In a conventional integrated circuit (IC) chip, a top side is typically designed for electrical connection to one or more electrodes and/or a ball grid array (BGA) by wire bond, solder balls, and/or other suitable elements, and a bottom side is electrically isolated such that a substrate under a silicon chip area can be designed purely for heat dissipation. For example, in the CMOS chip illustrated in FIG. 1, electrical current does not flow down to a silicon wafer 110 because a buried silicon dioxide (SiO₂) layer 112 electrically isolates the silicon wafer 110. Accordingly, the bottom side of the IC chip is electrically insulated in conventional IC chip designs, and electric current flows out one surface (e.g., the top surface) rather than vertically through the IC chip.

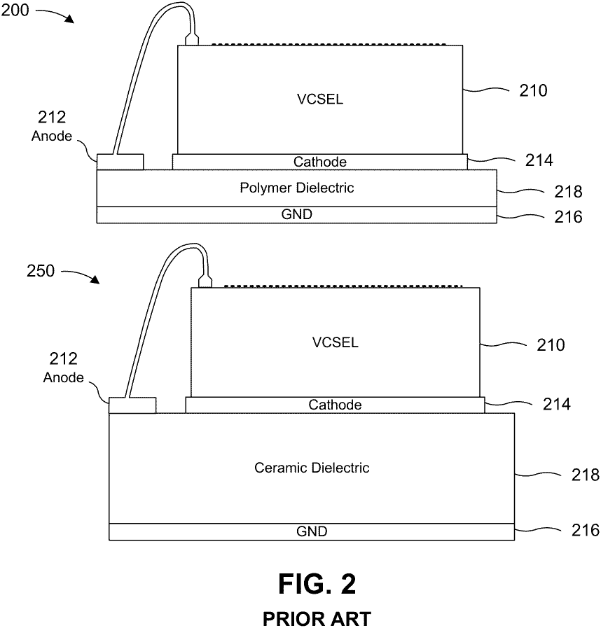

In contrast, a vertical-cavity surface-emitting laser (VCSEL) chip is generally designed to emit a laser beam in a direction perpendicular to a substrate surface (e.g., vertically from a surface of a semiconductor wafer), which differs from conventional IC chip designs in that electrical current and heat both flow from a top surface of the VCSEL chip to the bottom surface and then to a die pad or cathode layer. For example, FIG. 2 is a diagram illustrating examples 200, 250 of top-emitting VCSEL chips connected to a substrate. As shown in FIG. 2, examples 200, 250 each generally include a VCSEL chip 210 that emits a laser beam in a vertical direction, and the VCSEL chip 210 is connected to a substrate that includes an anode 212, a cathode 214, a ground layer 216, and a dielectric layer 218 that separates the anode 212 and the cathode 214 from the ground layer 216. For example, as shown in FIG. 2, electric current flows from the anode 212 to the top surface of the VCSEL chip 210, vertically through the VCSEL chip 210 to the cathode 214, and then horizontally through the cathode 214 to a neighboring controller, an IC driver, and/or another suitable component (not shown in FIG. 2). Accordingly, because both heat and electrical current flow vertically through the VCSEL chip 210 from the anode 212 to the cathode 214, the underlying substrate needs to have at least two metal layers (e.g., a first metal layer for forming the ground layer 216 and a second metal layer for forming the anode 212 and cathode 214). For example, in the examples 200, 250 shown in FIG. 2, heat flows from the VCSEL chip 210 through the cathode 214, the dielectric layer 218, and the ground layer 216, where the dielectric layer 218 has the largest thermal resistance due to the low thermal conductivity of the dielectric material(s) used in the dielectric layer 218.

For example, in the underlying substrate design, the cathode 214 is needed to enable electric current to flow through the VCSEL chip 210 to the neighboring controller, IC driver, and/or other suitable component(s), and the ground layer 216 is needed under the cathode 214 to support high-speed signals. Accordingly, the dielectric layer 218 is needed to electrically insulate the electric current that flows horizontally through the cathode 214 and to separate the cathode 214 from a heat dissipation pad on the substrate bottom (e.g., because the heat dissipation pad is typically electrically grounded and cannot be connected to the cathode 214 directly). However, the dielectric layer 218 that is needed between the cathode 214 and the ground layer 216 poses various design challenges. In particular, because both heat and electric current flow vertically through the VCSEL chip 210, the dielectric layer 218 needs to provide electrical insulation for the electric current, and the dielectric layer 218 further needs to have a low thermal resistance such that a heat dissipation pad (not shown) under the ground layer 216 can dissipate and/or spread the heat that flows vertically through the VCSEL chip 210.

For example, in example 200, the VCSEL chip 210 is connected to a substrate that includes a dielectric layer 218 made from a polymer dielectric material, such as flame retardant 4 (FR4 or FR-4), which is a flame resistant or self-extinguishing composite material made from woven fiberglass cloth with an epoxy resin binder. In such cases, when the dielectric layer 218 is made from a polymer dielectric such as FR4, the dielectric layer 218 has a very low thermal conductivity (e.g., approximately 0.3 to approximately 0.7 watts per meter-kelvin (W/mK)). As a result, even if advanced substrate technology were to be used to form the dielectric layer 218 with a minimum thickness for the chosen polymer dielectric material (e.g., 25 micrometers (µm) for FR4) to optimize electrical performance (e.g., by minimizing parasitic inductance across the dielectric layer 218, between the cathode 214 and the ground layer 216), the low thermal conductivity of the polymer dielectric material results in a high thermal resistance (e.g., 46.61° C. per watt (C/W) for FR4). In other words, the very high thermal resistance of polymer dielectric materials blocks the dissipation and/or spreading of heat that flows vertically through the VCSEL chip 210, which in turn downgrades optical output power from the VCSEL chip 210 (e.g., the high thermal resistance impacts power conversion efficiency of the VCSEL chip 210).

Alternatively, in example 250, the VCSEL chip 210 is connected to a substrate in which the dielectric layer 218 is made from a ceramic material (e.g., aluminum (Al) nitride (AlN) or aluminum oxide (Al₂O₃)). In such cases, the thermal conductivity of the ceramic dielectric material may be somewhat higher than the thermal conductivity of a polymer dielectric material (e.g., 130 W/mK for AlN or 15 W/mK for Al₂O₃ at a typical VCSEL operating temperature). However, in cases where a ceramic material is used to form the dielectric layer 218, the dielectric layer 218 may have a large thickness (e.g., a minimum thickness of 100 µm for AlN, or a minimum thickness of 70 µm for Al₂O₃) due to substrate manufacturing constraints. Accordingly, thermal resistance of the dielectric layer 218 is not significantly reduced due to the very large thickness of the dielectric layer 218, which also increases parasitic inductance to a higher level that has an impact on high-speed signal quality (e.g., by degrading high-speed modulation performance, increasing a rise time, and/or degrading a light detection and ranging (LiDAR) detection accuracy, among other examples). In other words, although ceramic dielectric materials such as AlN and Al₂O₃ generally have better thermal conductivity (e.g., lower thermal resistance) than polymer dielectric materials such as FR4, the large thickness of the ceramic dielectric layer 218 in example 250 results in suboptimal thermal performance (e.g., insufficient heat spreading and dissipation) and suboptimal electrical performance (e.g., a very high parasitic inductance).

Accordingly, existing substrates that are typically used in the IC packaging industry suffer from various drawbacks that degrade performance of a VCSEL chip 210 in cases where heat and electrical current flow vertically through the VCSEL chip 210 (e.g., because the dielectric layer 218 used in the substrate connected to the VCSEL chip 210 is typically made from one or more dielectric materials that have a high thermal resistance and/or a large minimum thickness that leads to a higher parasitic inductance). Furthermore, the drawbacks associated with existing dielectric materials are worse for VCSEL chips 210 that are operated using high-speed signals, which generally require more power, thereby resulting in more heat to be dissipated and/or spread and/or greater sensitivity to parasitic inductance. Furthermore, although some thin dielectric coating systems allow inorganic materials (e.g., aluminum oxynitride (AlON), AlN, aluminum phosphate (AlPO₄), and/or Al₂O₃) to be used as a coating material, these materials are usually incompatible with lamination processes used in the polymer dielectric (e.g., FR4) substrate industry and with co-firing processes used in the high temperature co-fired ceramic (HTCC) substrate industry.

Some implementations described herein relate to one or more substrate designs in which a first metal layer is separated from a second metal layer by one or more thin dielectric layers (or dielectric coatings) that may have a thickness in a range from 0.01 µm to 60 µm. For example, in some implementations, a substrate may include a ceramic core with various vias through the ceramic core, where the vias may be filled with a metal that has a high thermal conductivity (e.g., copper, copper-tungsten, or aluminum) to enable heat dissipation or spreading. In addition, the substrate may include a first metal layer and a second metal layer on a top surface of the ceramic core, and a thin dielectric layer is used to separate the first metal layer from the second metal layer. The dielectric coating layers may generally have a thickness less than approximately 60 µm and may have a thickness that is less than 25 µm in the case of AlON, AlN, or AlPO₄ (e.g., going as low as 0.01 to 5 µm for AlPO₄), which may result in a low parasitic inductance. Furthermore, the dielectric coating layers may be made from a dielectric material (e.g., AlON, AlN, AlPO₄, and/or Al₂O₃) that has a low thermal resistance (e.g., when the dielectric coating layers have a thickness of approximately 60 µm or less).

In this way, some implementations described herein relate to one or more substrate designs and one or more package (e.g., hybrid substrate) designs that may satisfy thermal and electrical performance requirements in circuits where heat and electrical current flows vertically across different metal layers. For example, as described herein, a dielectric layer used to electrically isolate a metal contact may be designed to have a low parasitic inductance and a low thermal resistance. For example, because the dielectric layer is thin (e.g., generally less than 60 µm, and potentially as thin as 0.01 µm), the dielectric layer is associated with a low parasitic inductance (e.g., because the parasitic inductance is proportional to a size of a current loop formed across the dielectric layer and vertically between two metal layers, whereby a thinner dielectric layer reduces parasitic inductance by reducing the size of the current loop). Furthermore, because the dielectric layer is thin and made from a dielectric material with a high thermal conductivity, the dielectric layer does not interfere with the heat spreading and/or heat dissipation properties of the metal-filled vias that are formed in the ceramic core. For example, the following table indicates thermal resistance and parasitic inductance properties for various dielectric materials, including FR4 and AlN layers with a minimum thickness of 100 µm, which suffer from degraded optical output power due to high thermal resistance, poor high-speed signal quality due to a large thickness increasing electrical inductance, and/or incompatibility with lamination, co-firing, and/or other manufacturing processes used in the substrate industry. In addition, the following table indicates thermal resistance and parasitic inductance properties for AlON that may be grown to a 20 µm thickness on a metal layer, where AlON grown on copper (Cu) or copper-tungsten (CuW) exhibits comparable thermal resistance as AlN but a much lower parasitic inductance due to the very small thickness.

TABLE 1

Thermal resistance and parasitic inductance for different dielectric materials

| | | |
|---|---|---|
| Dielectric material: Thickness | Thermal resistance | Parasitic inductance |
| FR4; 25 µm | 46.61 C/W | Medium |
| AlN; 100 µm | 12.92 C/W | High |
| AlPO4: 2×0.5 µm (on 100 µm Cu) | 12.33 C/W | Low |
| AlON; 2×20 µm (on 100 µm Cu) | 12.58 C/W | Low |
| AlON; 2×20 µm (on 100 µm CuW) | 12.78 C/W | Low |

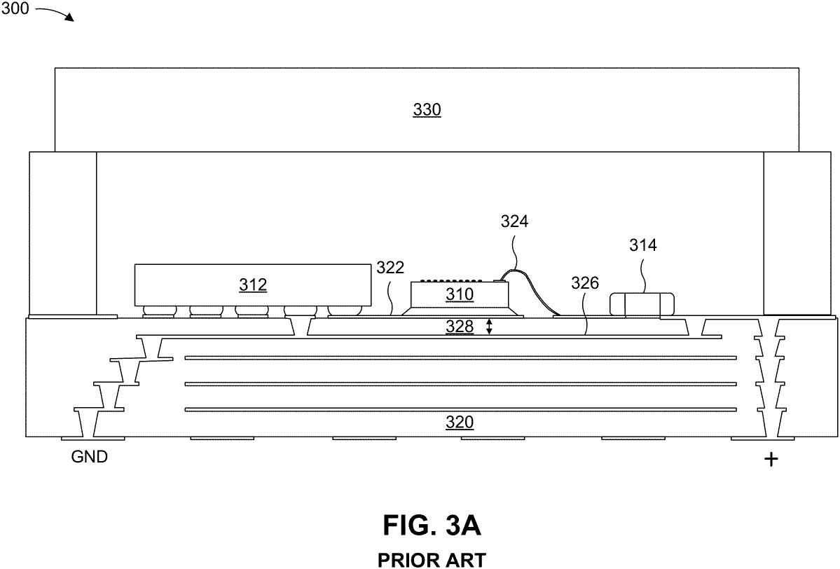

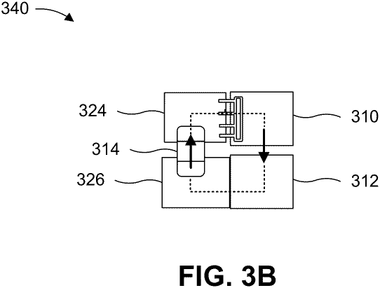

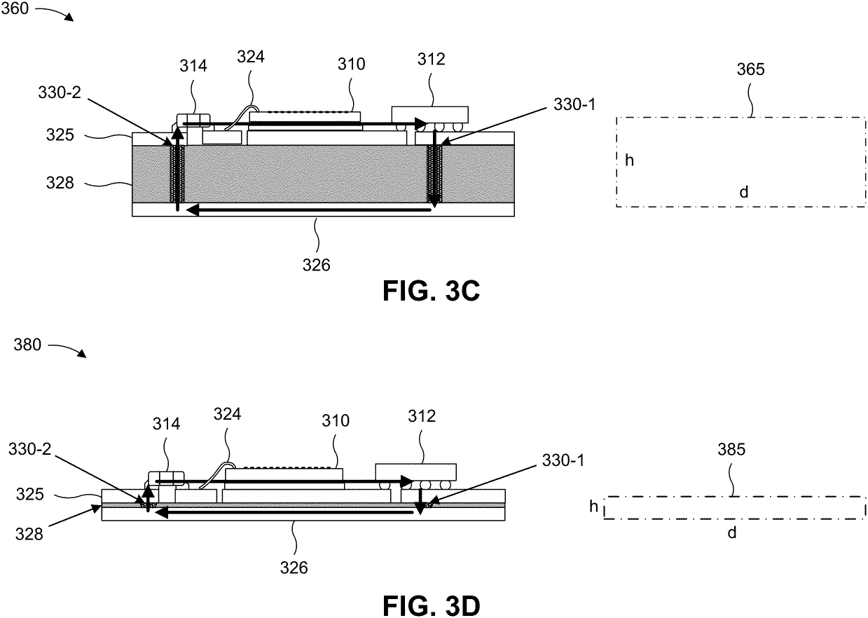

FIG. 3A is a diagram illustrating an example of a time-of-flight (ToF) projector module 300 in which a current loop may be formed to drive an optical load, and FIGS. 3B-3D are diagrams illustrating examples 340, 360, 380 of the current loop that may be used to drive the optical load in the ToF projector module 300. For example, as shown in FIG. 3A, the ToF projector module 300 may include a substrate 320 (e.g., an FR4 or HTCC substrate) with a top metal layer that includes a cathode 322 electrically connected to a bottom side of a VCSEL 310 and electrically connected to a driver 312, and the top metal layer may further include an anode 324 (shown as being electrically connected to one or more capacitors 314 and electrically connected to a top side of the VCSEL 310 using a wire bond). Furthermore, as shown, the substrate 320 includes a ground layer 326 as a second metal layer below the top metal layer, and a dielectric layer 328 that separates the top metal layer from the ground layer 326. Accordingly, when an electrical current flows through a set of circuit components arranged on the top metal layer (e.g., the VCSEL 310, the driver 312, and the capacitor(s) 314), the electrical current may cause the VCSEL 310 to emit a laser beam in a vertical direction through an optical element 330 (e.g., a diffractive optical element (DOE), a diffuser, a window, and/or a lens, among other examples), such that the ToF projector module 300 may be used as a VCSEL-based projector in a three-dimensional (3D) sensing camera application. However, as described in further detail above, the dielectric layer 328 that is provided between the top metal layer and the ground layer 326 poses various design challenges because the dielectric layer 328 needs to be very thin in order to avoid parasitic inductance and needs to also have a low thermal resistance to enable heat dissipation.

For example, FIGS. 3B-3D illustrate examples 340, 360, 380 of electrical layouts that may be used to generate a high-speed current loop sufficient to drive a VCSEL array or another suitable optical load (e.g., in a ToF camera application). For example, one design challenge that arises in ToF applications is the need to reduce the parasitic inductance of the current loop that is needed to drive the VCSEL array (or other optical load) with a high speed and a high current. As shown in FIGS. 3B-3D, the high speed current loop may generally include a VCSEL 310, a driver 312, and one or more capacitors 314. In general, the electrical layout used to generate the high speed current loop may be implemented in one horizontal layer, or vertically in multiple metal layers. For example, in FIG. 3B, the current loop is provided in one horizontal layer, shown in a top view. In this case, a self-inductance of the current loop is proportional to a total length (or perimeter) of the current loop.

Alternatively, FIG. 3C and FIG. 3D illustrate examples 360, 380 in which the current loop is provided vertically in two metal layers, shown in a side view. For example, as shown in FIG. 3C and FIG. 3D, the current loop may pass horizontally through one or more capacitors 314, a VCSEL 310, and a driver 312 that are arranged along a top metal layer 325 (e.g., a Cu, CuW, or Al metal layer), vertically through a first metal-filled via 330-1, horizontally through a second metal layer 326 connected to ground, and through a second metal-filled via 330-2. In such cases, the dielectric layer 328 may need to be as thin as possible in order to provide a low parasitic inductance, and the dielectric layer 328 also needs to have a low thermal resistance in order to enable heat dissipation and/or heat spreading in the second metal layer 326. However, satisfying the electrical and thermal requirements for a high-speed current loop is difficult when existing dielectric materials are used to form the dielectric layer 328.

For example, in FIG. 3C, example 360 depicts an arrangement in which the dielectric layer 328 is made from a ceramic material (e.g., Al₂O₃ or aluminum nitride (AlN) HTCC), in which case the dielectric layer 328 may have a large thickness (e.g., a minimum thickness of 100 µm for AlN, or a minimum thickness of 70 µm for Al₂O₃, and a thickness greater than 150 µm for two layers due to processing and material restrictions). As a result, even though the ceramic dielectric material may have a somewhat higher thermal conductivity than a polymer dielectric such as FR4 (e.g., 130 W/mK for AlN or 15 W/mK for Al₂O₃ at a typical VCSEL operating temperature), the ceramic dielectric material may still cause thermal problems for VCSELs, laser chips, and/or other devices that generally are more power efficient at lower temperatures. For some applications (e.g., an automotive LiDAR sensor), a laser peak power can be as high as hundreds of watts, whereby a substrate design that has a low thermal resistance is desirable. Furthermore, the large thickness of the dielectric layer 328 increases parasitic inductance to a higher level that has an impact on high-speed signal quality (e.g., by degrading high-speed modulation performance). Furthermore, to the extent that other dielectric materials such as FR4 associated with a minimum thickness of 25 µm may be used, such dielectric materials have a prohibitively high thermal resistance that is unsuitable for use in the ToF projector module 300 that needs to spread and/or dissipate the large amount of heat that is generated by the high speed current loop.

For example, as shown by reference number 365, the rectangular shaped current loop may have a self-inductance approximately proportional to an area of the current loop, defined using the expression h*d, where d is a horizontal dimension of the circuit components forming the current loop (e.g., the capacitor(s) 314, the VCSEL 310, and the driver 312), and h is a vertical dimension of the layers forming the current loop (e.g., a combined thickness of the top metal layer 325 and the dielectric layer 328). In general, the horizontal dimension d is typically limited by the size of the circuit components. However, the vertical dimension h of the current loop may vary depending on the thickness of the dielectric layer 328.

Accordingly, in FIG. 3D, example 380 illustrates a design in which the dielectric layer 328 separating the top metal layer 325 from the second metal layer 326 is a thin dielectric coating, such as AlON, AlN, or AlPO₄ with a thickness in a range between 0.2 µm (or 200 nanometers) and 60 µm, which significantly reduces the self-inductance of the current loop and provides the heat dissipation needed for high speed and high current operation. Accordingly, as shown by reference number 385, reducing the thickness of the dielectric layer 328 can significantly reduce the vertical dimension h of the current loop and thereby significantly reduce the self-inductance. For example, using a thin dielectric coating as the dielectric layer 328 (e.g., as shown in FIG. 3D) may reduce the vertical dimension h to be less than 50 µm, which may result in a 2x reduction in the self-inductance.

For example, as described herein, the thickness of the dielectric layer 328 may be approximately 5 µm to 20 µm for AlON or approximately 0.2 µm to 5 µm for AlPO₄ dielectric materials, and the thickness of the top metal layer 325 may be 18 µm, which may result in the vertical dimension h having a maximum value of 38 µm in cases where AlON or AlPO₄ is used to form the dielectric layer 328. Accordingly, whereas the self-inductance in a current loop formed horizontally in one metal layer is generally proportional to the total length of the current path (e.g., 2h + 2d, as in FIG. 3B), the total self-inductance of the current loop formed in two metal layers is proportional to the area enclosed by the current loop (e.g., h*d). Therefore, reducing the vertical dimension h by a given amount (e.g., 1 µm) will generally have a larger impact with respect to reducing the total inductance relative to reducing the horizontal dimension d by the same amount in a design where the total inductance of the current loop is proportional to the total length of the current path. Also, reducing either dimension by a given amount will have a larger impact on the total inductance when the inductance is proportional to the area (e.g., h*d for vertical current loops) rather than the perimeter (e.g., 2h + 2d for horizontal current loops).

Some implementations described in further detail herein therefore relate to a substrate design that includes a thin dielectric layer to separate a first metal layer and a second metal layer when a current loop is formed vertically across the first metal layer and the second metal layer. In this way, where a high speed current loop is formed in two metal layers, using a thin dielectric layer between the top metal layer 325 and the second metal layer 326 (e.g., as shown in FIG. 3D) may reduce the self-inductance by more than 2x compared to a design that utilizes a conventional HTCC or thin film substrate (e.g., as shown in FIG. 3C), in addition to providing significantly lower thermal resistance than other thin dielectric materials associated with a prohibitively low thermal conductivity or a prohibitively high thermal resistance when used in high speed, high current applications such as a ToF camera projector module. For example, although FR4 may be formed with a minimum thickness of 25 µm using advanced substrate technology, which provides a lower parasitic inductance than an HTCC dielectric with a minimum thickness of 100 µm, FR4 is associated with a very low thermal conductivity (e.g., between 0.3 to 0.7 W/mK) and a very high thermal resistance (e.g., 46.61 C/W at the minimum thickness of 25 µm), whereby FR4 is unsuitable to dissipate and/or spread the heat that is generated by a high-power VCSEL-based ToF projector module.

As indicated above, FIGS. 3A-3D are provided as examples. Other examples may differ from what is described with regard to FIGS. 3A-3B.

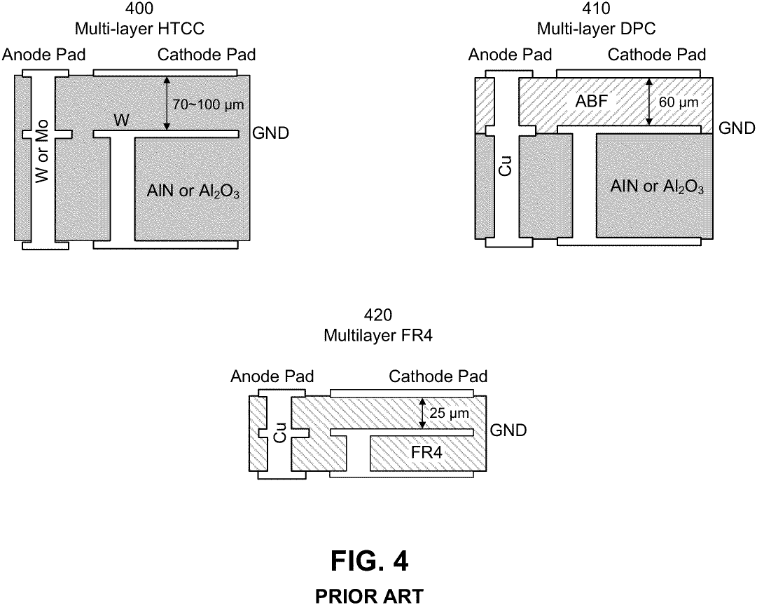

FIG. 4 is a diagram illustrating examples 400, 410, 420 of substrates with a high thermal resistance and/or a high parasitic inductance.

In particular, as described above, existing substrates that are typically used in the IC packaging industry suffer from drawbacks that make the existing substrates generally unsuitable for use with a VCSEL chip where heat and electrical current flow vertically through the VCSEL chip. In particular, a dielectric layer used in a substrate for a VCSEL chip is typically made from a dielectric material that has a very large minimum thickness that leads to a higher parasitic inductance, which increases a rise time and/or degrades LiDAR detection accuracy. Additionally, or alternatively, the dielectric material used for the dielectric layer in the substrate may have a very high thermal resistance that impacts a power conversion efficiency and therefore reduces optical output power of the VCSEL chip. For example, referring to FIG. 4, example 400 depicts a multi-layer HTCC substrate in which a first dielectric layer separating a cathode pad from a metal layer or trace connected to ground is made from Al₂O₃, which has a minimum thickness of 70 µm, or from AlN, which has a minimum thickness of 100 µm. Accordingly, because the dielectric layer has a very large thickness in example 400, the multi-layer HTCC substrate has a high parasitic inductance, a high electrical resistance, and a moderate thermal resistance. In another sub-optimal design, shown by example 410, a multi-layer directly plated Cu (DPC) substrate includes a first dielectric layer made from a build-up film (e.g., Ajinomoto build-up film (ABF)), which has a minimum thickness of 60 µm, which results the multi-layer DPC substrate shown in FIG. 4 having a high parasitic inductance and a high thermal resistance despite offering a low electrical resistance. In another sub-optimal design, shown by example 420, a multi-layer FR4 substrate includes a first dielectric layer made from a material with a very high thermal resistance despite having a minimum thickness of 25 µm that may offer a lower parasitic inductance and/or a lower electrical resistance than the multilayer HTCC substrate and/or the multilayer DPC substrate respectively shown by examples 400 and 410.

Accordingly, some implementations described herein relate to ceramic core substrate designs that use thin dielectric materials such as AlON, AlPO₄, Al₂O₃, and/or SiO₂ to separate adjacent metal layers, which may enable more layers for signal routing and enable multiple capacitors to be easily and/or freely integrated into a ToF projector module.

For example, as described in further detail herein, some implementations relate to multi-layer DPC substrates that include a ceramic core that may be made from AlN, Al₂O₃ or another suitable ceramic material and one or more thin dielectric layers that are made from a dielectric material such as AlON (e.g., with a thickness in a range from 1 µm to 60 µm), AlPO₄ (e.g., with a thickness in a range from 0.01 µm to 60 µm), Al₂O₃ (e.g., with a thickness in a range from 0.3 µm to 1 µm), and/or SiO₂ (e.g., with a thickness in a range from 0.3 µm to 1 µm). For example, in some implementations, the substrate may include a rigid ceramic core DPC substrate including one or more through vias (e.g., that may be premanufactured in the ceramic core), which may be filled with metal (e.g., Cu) to enable thermal heat dissipation and reduce a distance between one or more metal contacts and a ground layer (e.g., thereby reducing parasitic inductance and/or electrical resistance). The top side of the ceramic core DPC substrate may be uniformly coated with a thin dielectric layer, which may cover the top surface and sidewalls of the metal traces in an M3 layer. In some implementations, one or more vias may then be drilled through the thin dielectric layer to provide electrical connections between one or more of the metal traces in the M3 layer and one or more contacts to be formed on the thin dielectric layer. In some implementations, formation of the vias through the thin dielectric layer may be followed by metal (e.g., Cu) plating and etching to form an M2 layer, which may include a first contact (e.g., an anode) that is electrically isolated from an underlying metal trace in the M3 layer and one or more contacts (e.g., a cathode and a ground) that are electrically connected to underlying metal traces in the M3 layer by the via(s) formed in the thin dielectric layer. Accordingly, because the dielectric layer on the top surface of the ceramic core is very thin, the thin dielectric layer significantly reduces parasitic inductance and electrical resistance that may otherwise increase a rise time and/or degrade LiDAR performance. Furthermore, the thin dielectric layer is made from a material that has a low to moderate thermal resistance, which reduces thermal resistance that may otherwise reduce power conversion efficiency of a VCSEL or other high-speed electro-optical chip that may be connected to the contact that is electrically isolated from the underlying metal trace in the M3 layer. Furthermore, in some implementations, a second thin dielectric layer may be provided on the bottom side of the ceramic core to increase the number of layers that are available for circuit and/or signal routing.

As indicated above, FIG. 4 is provided as one or more examples. Other examples may differ from what is described with regard to FIG. 4.

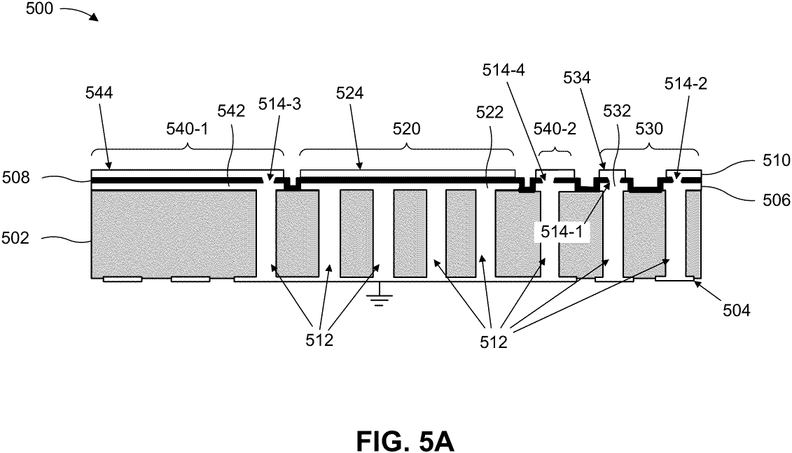

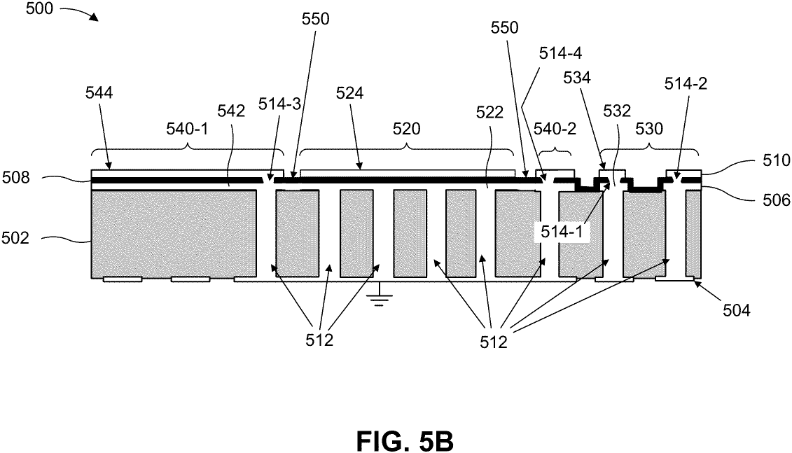

FIGS. 5A-5B are diagrams illustrating example implementations of a substrate 500 with an thin dielectric layer to enable a low thermal resistance and a low parasitic inductance. For example, as shown in FIGS. 5A-5B, the substrate 500 may include a ceramic core 502 (e.g., an AlN or Al₂O₃ core) having a top side, a bottom side, and multiple metal-filled vias 512 (e.g., Cu-filled vias) through the ceramic core 502. As further shown, the substrate 500 may include a first metal layer 506 (e.g., an M3 layer), on the top side of the ceramic core 502. As further shown, the first metal layer 506 includes a first metal trace 522 over a first metal-filled via 512 in a first region 520, a second metal trace 532 over a second metal-filled via 512 in a second region 530, and a third metal trace 542 over a third metal-filled via 512 in a third region 540. As described herein, the first region 520 is electrically isolated and associated with a low thermal resistance, the second region 530 provides electrical through-connections, a low parasitic inductance, and good thermal performance (e.g., high thermal conductivity), and the third region 540 provides an electrical ground, a low parasitic inductance, and good thermal performance. Furthermore, in some cases, there may be more than one first region 520, second region 530, and/or third region 540. For example, FIGS. 5A-5B illustrate example designs in which the substrate includes third regions 540-1 and 540-2, which may provide separate electrical ground contacts associated with a low parasitic inductance and good thermal performance. Furthermore, as described herein, the first region 520 may be suitable for providing electrical connections that are isolated from other electrical connections formed on or through the substrate 500, the second region 530 may be suitable for providing electrical connections through the ceramic core 502 that are separated from other electrical connections formed on or through the substrate 500, and the third region 540 may be suitable for providing electrical through connections to ground.

Furthermore, as shown in FIGS. 5A-5B, the substrate 500 includes a uniformly thick thin dielectric layer 508 (e.g., a thin film coating) on the first metal layer 506, which covers the top surfaces and sidewalls of the metal traces 522, 532, 542 in the M3 layer. In some implementations, as shown in FIG. 5A, electrical connectivity between the first metal traces 522, the second metal traces 532, and the third metal traces 542 is disconnected (e.g., the first metal traces 522 and the third metal traces 542 are electrically isolated) by removing portions of the first metal layer 506 therebetween and allowing the thin dielectric layer 508 to conform to the space left between the traces. In some implementations, to further reduce parasitic inductance and further reduce thermal resistance, the first metal traces 522 and the third metal traces 542 may remain electrically connected in the first metal layer 506. For example, as shown in FIG. 5B, reference number 550 depicts regions where portions of the first metal layer 506 are not removed such that the first metal traces 522 and the third metal traces 542 may remain electrically connected.

In some implementations, the thin dielectric layer 508 may be made from AlON with a thickness in a range from 1 µm to 60 µm (e.g., about 10 µm thick), which may be coated on the top surfaces and sidewalls of the metal traces 522, 532, 542 and on exposed portions of the ceramic core 502 (e.g., regions that are not covered by the metal traces 522, 532, 542 in the first metal layer 506) using physical vapor deposition (PVD), chemical vapor deposition (CVD), and/or another suitable technique. Additionally, or alternatively, the thin dielectric layer 508 may be made from AlPO₄ with a thickness in a range from 0.01 µm to 60 µm (e.g., about 0.2 µm thick), which may be coated on the top surfaces and sidewalls of the metal traces 522, 532, 542 and on the exposed portions of the ceramic core 502 using dip coating, spin coating, and/or another suitable technique. Additionally, or alternatively, the thin dielectric layer 508 may be made from Al₂O₃ or SiO₂ with a thickness in a range from 0.3 µm to 1 µm, which may be coated on the top surfaces and sidewalls of the metal traces 522, 532, 542 and on the exposed portions of the ceramic core 502 using PVD, CVD, and/or another suitable technique.

As further shown in FIGS. 5A-5B, the substrate 500 may include a second metal layer 510 (e.g., an M2 layer), which may include a first electrical contact 524 provided in the first region 520 over the first metal trace 522 (e.g., an anode for providing an electrical connection to a VCSEL in a current loop of a ToF projector module), a second electrical contact 534 provided in the second region 530 over the second metal trace 532 (e.g., a cathode for providing an electrical connection to a driver in the current loop of the ToF projector module), and a third electrical contact 544 provided in the third region 540 over the third metal trace 542 (e.g., for providing an electrical connection to a ground in the current loop of the ToF projector module). For example, starting from a rigid ceramic core DPC structure, the vias 512 may be formed through the ceramic core 502 (e.g., by drilling through the ceramic core 520 or using other suitable techniques) and then filled with a metal such as Cu. In some implementations, metal traces 522, 532, 542 may then be formed on the top side of the ceramic core 502 and a bottom metal layer 504 may be formed on the bottom side of the ceramic core 520. In some implementations, additional metal layers may be formed on the top side of the ceramic core 502 and to enable building up one or more metal layers (e.g., M3 and/or M4 layers).

For example, as described herein, an Mx layer (where x is a positive integer) may generally refer to a number of a metal layer relative to an exposed side (e.g., a topside) or a front-end region of a device, which usually ends at contacts of one or more devices that form a circuit (e.g., a capacitor, VCSEL, and driver in a ToF projector module). The M1 layer may be the lowest layer, commonly adjacent to a substrate, while the layer with the highest number would be the uppermost layer, often for interconnection to other devices. Between the M1-Mx layers would be electrical insulation layers, such as one or more dielectric layers. One or more traces may be formed in each metal layer and one or more vias may be formed within the electrical insulation layer(s) to interconnect various traces and thereby form circuit paths horizontally and/or vertically through the layers. Metallization layers M1-Mx are typically referred to as being located in the back-end region of the device, and are used to interconnect the devices in the front-end region of the device and also connect the devices to packaging connections (e.g., to ground in FIGS. 5A-5B). Furthermore, there may be one or more vias between the M layers, which may be used to form connections between the M layers, including one or more vias 514 through the thin dielectric layer 508. For example, in FIGS. 5A-5B, the thin dielectric layer 508 includes a pair of vias 514-1, 514-2 in the second region 530, a via 514-3 in region 540-1, and a via 514-4 in region 540-2 (note that there are no vias 514 through the thin dielectric layer 508 in the first region 520 to ensure that the electrical contact 524 is electrically isolated. Accordingly, as described herein, the vias 514-1 and 514-2 that are formed through the thin dielectric layer 508 in the second region 530 may provide electrical connections between the electrical contacts 534 and the underlying metal traces 532 in the second region 530, and the vias 514-3 and 514-4 may provide electrical connections between the electrical contacts 544 and the underlying metal traces 542 in the third region 540.

In this way, due to the vias 514-1 and 514-2 providing the electrical connections between the electrical contacts 534 and the metal traces 532 in the second region 530, the electrical contacts 534 in the second region 530 may provide electrical through-connections (e.g., through the ceramic core 502) with a low inductance and a low thermal resistance, which may be suitable for using the second electrical contact 534 as a signal pad or a cathode pad that is separated from other electrical connections (e.g., for connecting a driver in a ToF projector module). Furthermore, due to the vias 514-3 and 514-4 providing the electrical connections between the electrical contacts 544 and the metal traces 542, which are formed over the metal-filled vias 512 in the third region 540, the electrical contacts 544 in the third region 540 may provide electrical through-connections (e.g., through the ceramic core 502) to ground with a low inductance and low thermal resistance, which may be suitable for using the electrical contacts 544 in the third region 540 as ground pads (e.g., for connecting a capacitor in a ToF projector module). While individual vias through the thin dielectric layer 508 have been illustrated and/or described, such as the vias 514-1, 514-2 in the second region 530 and the vias 514-3, 514-4 in the third region 540, more or fewer vias 514 may be provided as desired. Further, in FIGS. 5A-5B, the electrical contacts 544 in the third region 540 are depicted as a special case of signal pads that are electrically connected to ground. Furthermore, as shown, the thin dielectric layer 508 has no via 514 under the first electrical contact 524, which may be a design choice to electrically isolate a VCSEL chip or another high-speed electro-optical component that may be connected to the first electrical contact 524. For example, because there is no via 514 in the thin dielectric layer 508 under the first electrical contact 524, the first electrical contact 524 is isolated from other electrical connections, whereby the first electrical contact 524 in the first region 520 may provide a floating pad that can be configured as an anode pad or a cathode pad (e.g., depending on a configuration for a VCSEL chip or other high-speed electro-optical component to be connected to the first electrical contact 524). In addition, because the thin dielectric layer 508 is very thin and made from a dielectric material with a low thermal resistance, the first electrical contact 524 is associated with a low thermal resistance to dissipate and/or spread heat that may be generated by one or more devices connected to the first electrical contact 524.

Accordingly, in the substrate 500 depicted in FIGS. 5A-5B, the thin dielectric layer 508 on the top side (e.g., between the M2 and M3 layers, or first metal layer 506 and second metal layer 510) of the ceramic core 502 is very thin (e.g., no more than 60 µm, and potentially as thin as 0.01 µm), which significantly reduces parasitic inductance and electrical resistance. Furthermore, as described herein, the thin dielectric layer 508 is made from a material that has a low to moderate thermal resistance, such as AlON, AlPO₄, Al₂O₃, SiO₂, or the like, or the low to moderate thermal resistance may be caused by the dielectric layer 508 being very thin. Furthermore, in some implementations, the ceramic core 502 may include a third (bottom) metal layer 504, on the bottom side of the ceramic core 502, including respective metal contacts under metal-filled vias 512 that are connected to respective metal traces 522, 532, 542 under the first electrical contact 524 (e.g., an electrically isolated anode or floating pad), the second electrical contact 534 (e.g., a cathode or signal pad that provides a through-connection that is separated from other electrical connections), and the third electrical contact 544 (e.g., a ground or ground pad providing a through-connection to ground). Furthermore, in some implementations, the substrate 500 may include a fourth metal layer (not explicitly shown in FIGS. 5A-5B), under the third (bottom) metal layer 504, and a second thin dielectric layer (not explicitly shown in FIGS. 5A-5B) may separate the third (bottom) metal layer 504 and the fourth metal layer, thereby increasing the number of layers that are available for circuit and/or signal routing.

In some implementations, as shown in FIG. 5A, the first metal layer 506 may be separated into isolated traces 522 and 542 in the first region 520 and the third region, respectively. For example, as shown in FIG. 5A, portions of the first metal layer 506 between the traces 522 and 542 may be removed (e.g., using an etching technique, a drilling technique, or another suitable technique) such that the thin dielectric layer 508 can conform to the spaces left between the traces 522, 542. Additionally, or alternatively, as shown in FIG. 5B, the first metal layer 506 may be connected except for the metal trace 532 in the second region 530, which is used to carry signals through the core 502. In this way, connecting the traces 522, 542 (e.g., as shown in FIG. 5B) may provide a shorter current loop and reduced parasitic inductance relative to the design shown in FIG. 5A. Furthermore, although not explicitly illustrated in FIGS. 5A-5B, one or more features of the substrate 500 may be extended to complete a ground loop and thereby define the current loop that impacts the parasitic inductance associated with the substrate 500. For example, in some implementations, the metal contacts in the bottom metal layer 504 that are disposed underneath the metal traces 532 in the second region 530 may be extended to contact the metal-filled vias 512 that are coupled to ground and thereby complete the current loop.

As indicated above, FIGS. 5A-5B are provided as examples. Other examples may differ from what is described with regard to FIGS. 5A-5B.

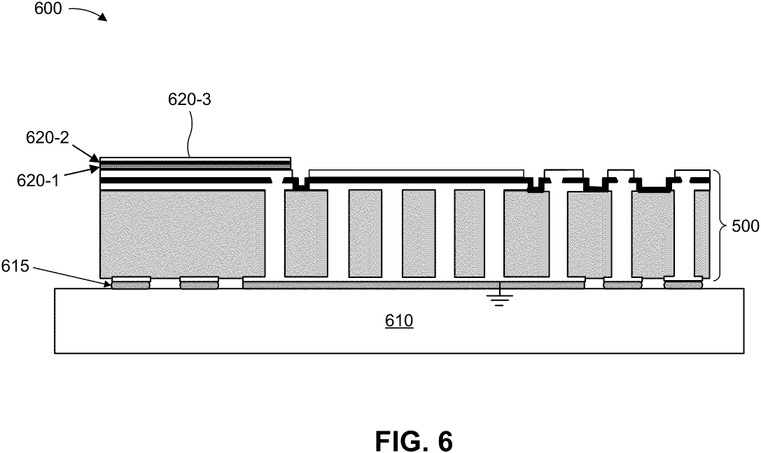

FIG. 6 is a diagram illustrating an example circuit 600 in which the substrate 500 shown in FIG. 5A is mounted to a printed circuit board (PCB) and an integrated capacitor 620 is formed on a top metal layer of the substrate 500. In some implementations, the circuit 600 may include a subset of components that (e.g., together with a driver and a high-speed electro-optical chip, such as a VCSEL chip) form a current loop that is formed vertically in substrate 500 and used to drive an optical load with a low thermal resistance, a low electrical resistance, and a low parasitic inductance. Furthermore, although FIG. 6 illustrates an implementation in which the example circuit 600 is implemented using the substrate 500 shown in FIG. 5A, the circuit 600 may be implemented using the substrate 500 shown in FIG. 5B (e.g., where the first metal layer 506 is connected to form a shorter current loop that provides a lower parasitic inductance).

For example, referring to FIG. 6, the example circuit 600 may be used in a ToF projector module with a thin-film capacitor. In FIG. 6, the circuit 600 includes a DPC substrate 500 with a single-side thin dielectric layer separating a first metal layer and a second metal layer on a top surface of a ceramic core, as described above with reference to FIGS. 5A-5B. However, it will be appreciated that in some cases the substrate 500 may include a second thin dielectric layer (not shown) on a bottom side of the ceramic core. In some implementations, the thin dielectric layer of the substrate 500 may include an AlON coating that is deposited with a uniform thickness in a range from 1 µm to 60 µm on the top surfaces and sidewalls of the metal traces and on exposed portions of the ceramic core using PVD or CVD, from an AlPO₄ coating deposited with a uniform thickness in a range from 0.01 µm to 60 µm using dip coating, spin coating, and/or another suitable technique, or an Al₂O₃ or SiO₂ coating deposited with a thickness in a range from 0.3 µm to 1 µm using PVD, CVD, and/or another suitable technique.

Accordingly, as shown in FIG. 6 and described herein, the circuit 600 may include a substrate 500 that comprises a ceramic core with multiple metal-filled vias through the ceramic core and a bottom metal layer on a bottom side of the ceramic core that is connected to ground. As further shown, the bottom metal layer may be electrically bonded to a PCB 610 by an electrically conductive attachment 615, such as solder or Ag epoxy. As further shown, the circuit 600 includes a first metal layer, on a top side of the ceramic core, which includes various metal traces over the metal-filled vias that are formed through the ceramic core of the substrate 500. The dielectric layer, which may comprise an AlON layer, an AlPO₄ layer, an Al₂O₃ layer, or an SiO₂ layer with a thickness in a range described herein, provides the circuit 600 with a low parasitic inductance and a low electrical resistance based on a thickness of the dielectric layer and a low thermal resistance based on the thickness of the dielectric layer and/or the material used for the dielectric layer. As further shown in FIG. 6, the circuit 600 may include a second metal layer, formed on the dielectric layer (e.g., after one or more vias are formed in the dielectric layer), where the second metal layer includes an anode (e.g., an electrically isolated contact, or floating pad), a cathode (e.g., an electrical through-connection, or signal pad, that is separated from other electrical connections), and a ground (e.g., a through-connection or pad connected to ground). Accordingly, as shown in FIG. 6, a capacitor 620 may be connected to the ground. Furthermore, when used in a ToF projector module, a VCSEL (not explicitly shown in FIG. 6) may be connected to the anode or floating pad, and a driver (not explicitly shown in FIG. 6) may be connected to the cathode or signal pad. In such cases, an optical element (not shown) may be placed in an open window above the VCSEL and attached to the underlying substrate 500 by a housing. Accordingly, a current loop that flows through the capacitor(s) 620, the VCSEL, and the driver (e.g., via the anode, cathode, and ground provided in the second metal layer of the substrate 500) may cause the VCSEL to emit a laser in a vertical direction through the optical element (e.g., a DOE, a diffuser, a window, or a lens).

For example, after the thin dielectric layer is applied to uniformly coat the top surfaces and sidewalls of the metal traces and one or more exposed surfaces on the top side of the ceramic core, one or more vias may be drilled or otherwise formed (e.g., etched) through the thin dielectric layer to provide electrical connections between the underlying metal traces and one or more electrical contacts to be formed over the vias and the underlying metal traces. In some implementations, forming the vias in the dielectric layer may then be followed by metal (e.g., Cu) plating and etching to form an M2 layer (e.g., the second metal layer). In some implementations, as shown in FIG. 6, a thin-film capacitor comprising multiple layers 620-1, 620-2, 620-3 may then be integrated onto the substrate 500 (e.g., in the third region that is electrically connected to ground). For example, in some implementations, the thin-film capacitor may include a first layer 620-1 that is deposited or otherwise formed on the anode pad using a high-K material such as barium titanate (BaTiO₃) or barium strontium titanate (BST) ((BaₓSr₁₋ₓ)TiO₃), a second layer 620-2 that may include nickel (Ni) plating on the high-K layer 620-1 layer, and a third layer 620-3 that is made from Cu plating or another suitable metal on the top side to form one or more vertical capacitors 620. Furthermore, in cases where more metal layers are needed for circuit routing capabilities, the additional metal layer(s) may be formed by locally laminating a layer comprising a build-up film (e.g., ABF) and/or a dielectric material (e.g., FR4) on the top surface of a portion of the M2 layer such that the VCSEL chip or other device to be provided in the first (e.g., electrically isolated) region can be directly bonded onto the anode in the M2 layer by Ag epoxy or another suitable adhesive material.

Alternatively, in some implementations, the capacitor 620 may comprise a one-dimensional (1D) in-silicon capacitor array. For example, in the case of a 1D addressable array of VCSELs, there may be a need to control each row in the array using multiple capacitors 620 (e.g., each emitter row in 1D addressable array of VCSELs connects to an individual capacitor 620). Accordingly, to satisfy the requirements of a 1D addressable VCSEL, the circuit 600 shown in FIG. 6 may include a substrate design in which a 1D (e.g., a 1×N) capacitor array is mounted on top of the substrate. For example, rather than depositing a high-K material and then performing Ni plating and Cu plating to form one or more vertical capacitors, a layer may be formed from a build-up film such as ABF or a dielectric material such as FR4 on the cathode provided in the second metal layer. Forming the layer from the build-up film may be followed by metal (e.g., Cu) plating and mounting the 1D array of capacitors 620 on the metal plating. Alternatively, in some implementations, a higher capacitance may be achieved by mounting a surface mount device (SMD) multi-layer ceramic capacitor (MLCC) onto the substrate 500 (e.g., by reflow).

As indicated above, FIG. 6 is provided as an example. Other examples may differ from what is described with regard to FIG. 6.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “bottom,” “above,” “upper,” “top,” or the like, may be used herein for ease of description to describe one element or feature’s relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A substrate, comprising:
a ceramic core;
a plurality of metal-filled vias through the ceramic core;
a first metal layer, on a top side of the ceramic core, including:
a first metal trace, over and connected to a first metal-filled via of the plurality of metal-filled vias,
a second metal trace, over and connected to a second metal-filled via of the plurality of metal-filled vias, and
a third metal trace, over and connected to a third metal-filled via of the plurality of metal-filled vias,
wherein the second metal trace is electrically isolated from the first metal trace and the third metal trace;
a thin dielectric layer on the first metal layer,
wherein the thin dielectric layer has a low thermal resistance based on one or more of the thickness of the thin dielectric layer or a material used for the thin dielectric layer; and
a second metal layer, on the thin dielectric layer, including:
a first electrical contact over the first metal trace and electrically isolated from the first metal trace,
a second electrical contact over the second metal trace and electrically connected to the second metal trace, and
a third electrical contact over the third metal trace and electrically connected to the third metal trace,
wherein the second electrical contact is electrically isolated from the first electrical contact and the third electrical contact.

2. The substrate of claim 1, wherein the first electrical contact is electrically isolated from the first metal layer.

3. The substrate of claim 1, wherein the first metal trace is electrically isolated from the second metal trace and the third metal trace, wherein the thin dielectric layer covers top surfaces and sidewalls of the first metal trace, the second metal trace, and the third metal trace, and wherein the thin dielectric layer covers exposed portions of the top side of the ceramic core.

4. The substrate of claim 1, wherein the thin dielectric layer includes a first via, through the thin dielectric layer, to provide an electrical connection between the second electrical contact and the second metal trace and a second via, through the thin dielectric layer, to provide an electrical connection between the third electrical contact and the third metal trace.

5. The substrate of claim 1, wherein the thin dielectric layer is a thin film coating formed on the first metal layer.

6. The substrate of claim 1, wherein the material used for the thin dielectric layer includes aluminum oxynitride (AlON) or aluminum phosphate (AlPO₄), and wherein the thickness of the dielectric coating is in a range from 0.01 micrometers to sixty micrometers.

7. The substrate of claim 1, wherein the material used for the thin dielectric layer includes aluminum oxide (Al₂O₃) or silicon dioxide (SiO₂), and wherein the thickness of the thin dielectric layer is in a range from 0.3 micrometers to one micrometer.

8. The substrate of claim 1, wherein the ceramic core is formed from aluminum nitride (A1N) or aluminum oxide (Al₂O₃).

9. The substrate of claim 1, further comprising:
a third metal layer, on a bottom side of the ceramic core, including:
a first metal contact, under and connected to the first metal-filled via and the third metal-filled via, and
a second metal contact, under and connected to the second metal-filled via,
wherein the second metal contact is electrically isolated from the first metal contact.

10. The substrate of claim 9, further comprising:
a fourth metal layer under the third metal layer; and
a second thin dielectric layer separating the third metal layer and the fourth metal layer.

11. A circuit, comprising:
a ceramic core comprising a plurality of metal-filled vias through the ceramic core;
a first metal layer, on a top side of the ceramic core, including a plurality of metal traces over and connected to the plurality of metal-filled vias,
wherein the plurality of metal traces include one or more first metal traces and one or more second metal traces,
wherein the one or more second metal traces are each electrically isolated from the rest of the plurality of metal traces;
a thin dielectric on the first metal layer,
wherein the thin dielectric has a low thermal resistance based on one or more of a thickness of the thin dielectric or a material used to form the thin dielectric;
a second metal layer, on the thin dielectric, including:
an anode over and electrically isolated from the plurality of metal traces by the thin dielectric;
a cathode over and electrically connected to at least one of the one or more second metal traces by a first via through the thin dielectric; and
a ground over and electrically connected to the one or more first metal traces by a second via through the thin dielectric; and
a capacitor connected to the ground,
wherein the thin dielectric between the first metal layer and the second metal layer provides the circuit with a low parasitic inductance and a low thermal resistance during operation.

12. The circuit of claim 11, wherein the material used for the thin dielectric includes aluminum oxynitride (AlON) or aluminum phosphate (AlPO₄), and wherein the thickness of the thin dielectric is in a range from 0.01 micrometers to sixty micrometers.

13. The circuit of claim 11, wherein the material used for the thin dielectric includes aluminum oxide (Al₂O₃) or silicon dioxide (SiO₂), and wherein the thickness of the thin dielectric is in a range from 0.3 micrometers to one micrometer.

14. The circuit of claim 11, wherein the ceramic core is formed from aluminum nitride (A1N) or aluminum oxide (Al₂O₃).

15. The circuit of claim 11, wherein the thin dielectric layer is a thin film coating formed on the first metal layer.

16. The circuit of claim 11, wherein the capacitor includes a thin-film capacitor that comprises:
a first layer, formed from a high-K material, on the ground;
a second layer, formed from nickel, on the first layer; and
a third layer, formed from a metal plating, on the second layer.

17. The circuit of claim 11, wherein the capacitor includes a one-dimensional capacitor array mounted on a metal layer separated from the ground by a dielectric layer.

18. The circuit of claim 11, wherein the capacitor includes a multi-layer ceramic capacitor mounted on a metal layer separated from the ground by a dielectric layer.

19. A method, comprising:
receiving a substrate that includes a ceramic core, a plurality of metal-filled vias through the ceramic core, and a first metal layer, on a top side of the ceramic core, including one or more metal traces;
depositing, on top of the ceramic core and the first metal layer, a dielectric layer that comprises:
an aluminum oxynitride (AlON) layer with a thickness in a range from one micrometer to sixty micrometers,
an aluminum phosphate (AlPO₄) layer with a thickness in a range from 0.01 micrometer to sixty micrometers,
an aluminum oxide (Al₂O₃) layer with a thickness in a range from 0.3 micrometers to one micrometer, or
a silicon dioxide (SiO₂) layer with a thickness in a range from 0.3 micrometers to ’one micrometer; and
forming, on the dielectric layer, a second metal layer including a floating contact over a first metal trace, a signal contact over a second metal trace, and a ground contact over a third metal trace.

20. The method of claim 19, further comprising:
forming, prior to forming the second metal layer, a first via through the dielectric layer for providing an electrical connection between the signal contact and the second metal trace; and
forming, prior to forming the second metal layer, a second via through the dielectric layer for providing an electrical connection between the ground contact and the third metal trace.

21. The method of claim 19, wherein the floating contact is electrically isolated from the first metal trace by the dielectric layer.
